(19) United States
(12) Patent Application Publication
(10) Pub. No.: US 2022/0149723 A1
(43) Pub. Date: May 12, 2022

(54) Power Electronics Module

(71) Applicant: Ticona LLC, Florence, KY (US)

(72) Inventors: Suresh Subramonian, Cary, NC (US); Prabuddha Bansal, Florence, KY (US); Young-Chul Yang, Seoul (KR); Cindy Choi, Gyeonggi-do Province (KR); Arno Wolf, Schonau (DE)

(21) Appl. No.: 17/521,994

(22) Filed: Nov. 9, 2021

Related U.S. Application Data
(60) Provisional application No. 63/235,264, filed on Aug. 20, 2021.
(60) Provisional application No. 63/111,823, filed on Nov. 10, 2020.

(51) Int. Cl. H02M 1/44; H02M 1/32; H05K 9/00

(52) U.S. Cl. CPC H02M 1/44; H05K 9/0081; H02M 1/32

(57) ABSTRACT

A power electronic module comprising a housing that receives at least one power converter is provided. The housing contains a polymer composition that includes an electromagnetic interference filler distributed within a polymer matrix. The polymer matrix contains a thermoplastic polymer having a deflection temperature under load of about 40° C. or more as determined in accordance with ISO 75-2:2013 at a load of 1.8 MPa. Further, the composition exhibits an electromagnetic interference shielding effectiveness of about 25 decibels or more as determined in accordance with ASTM D4935-18 at a frequency of 30 MHz and thickness of 3 millimeters.

### CROSS REFERENCE TO RELATED APPLICATIONS

The present application claims filing benefit of U.S. Provisional Patent Applications Ser. No. 63/111,823 having a filing date of Nov. 10, 2020 and 63/235,264 having a filing date of Aug. 20, 2021, which are incorporated herein by reference in their entirety.

### BACKGROUND OF THE INVENTION

Power electronics modules often include a power converter, such as an inverter, rectifier, voltage converter, etc., as well as combinations thereof (e.g., tandem inverter/rectifier units), to transform and/or condition power from one or more power sources for supplying power to one or more loads. Inverters, for instance, transform direct current (DC) to alternating current (AC) for use in supplying power to an AC load. In electric vehicles, for example, a source of direct current is typically available from a battery or power supply system incorporating a battery or other direct or rotating energy converter. Inverters are employed to convert this power to alternating current waveforms for driving one or more electric motors, which serve to drive power transmission elements to propel the vehicle. Likewise, rectifiers transform AC to DC and voltage converters, on the other hand, step up or step down a DC and/or AC voltage. When employed in electrical vehicles, one of the problems often encountered with power electronics modules is that they are susceptible to and/or can generate a substantial amount of electromagnetic interference (“EMI”), particularly in the ultralow frequency band of 150 kHz to 30 MHz. In this regard, various commercial standards, such as IEC CISPR 36:2020, have been developed to test electric vehicles of EMI. To help meet these standards, power converters are often placed within an aluminum housing that not only protects them from the external environment, but also acts as an EMI shield. Unfortunately, such components can add a substantial amount of cost and weight to the module, which is particularly disadvantageous when employed in an electrical vehicle as the automotive industry is continuing to require smaller and lighter components.

As such, a need currently exists for a power electronics module that does not require the need for additional EMI shields.

### SUMMARY OF THE INVENTION

In accordance with one embodiment of the present invention, a power electronics module is disclosed that comprises a housing that receives at least one power converter (e.g., inverter, rectifier, voltage converter, etc.). The housing contains a polymer composition that includes an electromagnetic interference filler distributed within a polymer matrix. The polymer matrix contains a thermoplastic polymer having a deflection temperature under load of about 40° C. or more as determined in accordance with ISO 75-2:2013 at a load of 1.8 MPa. Further, the composition exhibits an electromagnetic interference shielding effectiveness of about 25 decibels or more as determined in accordance with ASTM D4935-18 at a frequency of 30 MHz and a thickness of 3 millimeters.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 is an exploded perspective view of one embodiment of the power electronics module of the present invention;

FIG. 2 is a block diagram of certain functional circuitry of one embodiment of the power electronics module of the present invention for use in a vehicle drive system;

FIG. 3 is a diagram of one embodiment of the power electronics module of the present invention for use in a vehicle drive system;

FIGS. 4 and 5 are block diagrams of certain functional circuitry of one embodiment of the power electronics module of the present invention, including an inverter drive and a converter drive;

FIG. 6 is a schematic illustration of one embodiment of a system that may be used to form the polymer composition of the present invention;

FIG. 7 is a cross-sectional view of an impregnation die that may be employed in the system shown in FIG. 6;

FIG. 8 is a graph showing the shielding effectiveness (“SE”) for Sample 1 (thickness of 3 mm) over a frequency range from 30 MHz to 1.5 GHz; and

FIG. 9 is a graph showing the shielding effectiveness (“SE”) for Samples 2-4 (thickness of 3 mm) over a frequency range from 30 MHz to 1.5 GHz

### DETAILED DESCRIPTION

It is to be understood by one of ordinary skill in the art that the present discussion is a description of exemplary embodiments only, and is not intended as limiting the broader aspects of the present invention.

Generally speaking, the present invention is directed to a power electronics module that contains a power converter (e.g., inverter, rectifier, voltage converter, etc., as well as combinations thereof) within a housing. The housing contains a polymer composition that includes an EMI shielding filler distributed within a polymer matrix. The polymer matrix includes a high performance thermoplastic polymer having a relatively high degree of heat resistance, such as reflected by a deflection temperature under load (“DTUL”) of about 40° C. or more, in some embodiments about 50° C. or more, in some embodiments about 60° C. or more, in some embodiments from about from about 80° C. to about 250° C., and in some embodiments, from about 100° C. to about 200° C., as determined in accordance with ISO 75-2:2013 at a load of 1.8 MPa.

Through careful selection of the particular nature and concentration of the components of the polymer composition, the present inventors have discovered that the resulting composition can exhibit a high degree of shielding effectiveness to EMI. More particularly, the EMI shielding effectiveness (“SE”) may be about 25 decibels (dB) or more, in some embodiments about 30 dB or more, and in some embodiments, from about 35 dB to about 100 dB, as determined in accordance with ASTM D4935-18 at a low frequency, such as 30 MHz. Notably, it has been discovered that the EMI shielding effectiveness may remain stable over the low frequency range of from about 100 kHZ to about 1.5 GHz, in some embodiments from about 100 kHz to about 100 MHz, in some embodiments from about 30 MHz to about 100 MHz. In some cases, good shielding effectiveness can be achieved over a range of ultralow frequencies, such as from about 150 kHz to about 30 MHz. Of course, the EMI shielding effectiveness may also remain stable over higher frequency ranges, such as about 1.5 GHz or more, in some embodiments from about 1.5 GHz to about 18 GHz, in some embodiments from about 1.5 GHz to about 10 GHz, and in some embodiments, from about 2 GHz to about 9 GHz. The EMI shielding effectiveness may also be within the desired range for a variety of different part thicknesses, such as from about 0.5 to about 10 millimeters, in some embodiments from about 0.8 to about 5 millimeters, and in some embodiments, from about 1 to about 4 millimeters (e.g., 1, 1.5, 1.6, or 3 millimeters). Within these low frequency ranges and/or thickness ranges, for example, the average EMI shielding effectiveness may be about 25 dB or more, in some embodiments about 30 dB or more, and in some embodiments, from about 35 dB to about 100 dB. Likewise, the minimum EMI shielding effectiveness may be about 25 dB or more, in some embodiments about 30 dB or more, and in some embodiments, from about 35 dB to about 100 dB.

In addition to exhibiting good EMI shielding effectiveness, the composition may also exhibit a relatively low volume resistivity as determined in accordance with ASTM D257-14, such as about 25,000 ohm-cm or less, in some embodiments about 20,000 ohm-cm or less, in some embodiments about 10,000 ohm-cm or less, in some embodiments about 5,000 ohm-cm or less, in some embodiments about 1,000 ohm-cm or less, and in some embodiments, from about 50 to about 800 ohm-cm. The polymer composition may also be thermally conductive and thus exhibit an in-plane thermal conductivity of about 1 W/m-K or more, in some embodiments about 3 W/m-K or more, in some embodiments about 5 W/m-K or more, in some embodiments from about 7 to about 50 W/m-K, and in some embodiments, from about 10 to about 35 W/m-K, as determined in accordance with ASTM E 1461-13. The composition may also exhibit a through-plane thermal conductivity of about 0.3 W/m-K or more, in some embodiments about 0.5 W/m-K or more, in some embodiments about 0.40 W/m-K or more, in some embodiments from about 1 to about 15 W/m-K, and in some embodiments, from about 1 to about 10 W/m-K, as determined in accordance with ASTM E 1461-13.

Conventionally, it was believed that polymer compositions exhibiting good EMI shielding effectiveness, as well as low volume resistivity and/or thermal conductivity, would not also possess sufficiently mechanical properties. It has been discovered, however, that the polymer composition is still able to maintain excellent mechanical properties. For example, the polymer composition may exhibit a Charpy unnotched impact strength of about 20 kJ/m² or more, in some embodiments from about 30 to about 80 kJ/m², and in some embodiments, from about 40 to about 60 kJ/m², measured at according to ISO Test No. 179-1:2010) (technically equivalent to ASTM D256-10e1) at various temperatures, such as within a temperature range of from about −50° C. to about 85° C. (e.g., 23° C.). The tensile and flexural mechanical properties may also be good. For example, the polymer composition may exhibit a tensile strength of about 50 MPa or more 300 MPa, in some embodiments from about 80 to about 500 MPa, and in some embodiments, from about 85 to about 250 MPa; a tensile break strain of about 0.1% or more, in some embodiments from about 0.2% to about 5%, and in some embodiments, from about 0.3% to about 2.5%; and/or a tensile modulus of from about 3,500 MPa to about 30,000 MPa, in some embodiments from about 6,000 MPa to about 28,000 MPa, and in some embodiments, from about 8,000 MPa to about 25,000 MPa. The tensile properties may be determined in accordance with ISO Test No. 527-1:2019 (technically equivalent to ASTM D638-14) at various temperatures, such as within a temperature range of from about −50° C. to about 85° C. (e.g., 23° C.). The polymer composition may also exhibit a flexural strength of from about 100 to about 500 MPa, in some embodiments from about 130 to about 400 MPa, and in some embodiments, from about 140 to about 250 MPa; a flexural break strain of about 0.5% or more, in some embodiments from about 0.6% to about 5%, and in some embodiments, from about 0.7% to about 2.5%; and/or a flexural modulus of from about 4,500 MPa to about 60,000 MPa, in some embodiments from about 5,000 MPa to about 55,000 MPa, and in some embodiments, from about 5,500 MPa to about 50,000 MPa. The flexural properties may be determined in accordance with ISO Test No. 178:2019 (technically equivalent to ASTM D790-17) at various temperatures, such as within a temperature range of from about −50° C. to about 85° C. (e.g., 23° C.).

Various embodiments of the present invention will now be described in more detail.

### I. Polymer Matrix

A. Thermoplastic Polymers

The polymer matrix typically constitutes from about 30 wt. % to about 99 wt. %, in some embodiments from about 35 wt. % to about 90 wt. %, and in some embodiments, from about 40 wt. % to about 80 wt. % of the composition. The polymer matrix generally employs one or more high performance, thermoplastic polymers having a high degree of heat resistance, such as noted above. In addition to exhibiting a high degree of heat resistance, the thermoplastic polymers also typically have a high glass transition temperature, such as about 10° C. or more, in some embodiments about 20° C. or more, in some embodiments about 30° C. or more, in some embodiments about 40° C. or more, in some embodiments about 50° C. or more, and in some embodiments, from about 60° C. to about 320° C. When semi-crystalline or crystalline polymers are employed, the high performance polymers may also have a high melting temperature, such as about 140° C. or more, in some embodiments from about 150° C. to about 400° C., and in some embodiments, from about 200° C. to about 380° C. The glass transition and melting temperatures may be determined as is well known in the art using differential scanning calorimetry (“DSC”), such as determined by ISO 11357-2:2020 (glass transition) and 11357-3:2018 (melting).

Suitable high performance, thermoplastic polymers for this purpose may include, for instance, polyolefins (e.g., ethylene polymers, propylene polymers, etc.), polyamides (e.g., aliphatic, semi-aromatic, or aromatic polyamides), polyesters, polyarylene sulfides, liquid crystalline polymers (e.g., wholly aromatic polyesters, polyesteramides, etc.), polycarbonates, polyethers (e.g., polyoxymethylene), etc., as well as blends thereof. The exact choice of the polymer system will depend upon a variety of factors, such as the nature of other fillers included within the composition, the manner in which the composition is formed and/or processed, and the specific requirements of the intended application.

Aromatic polymers, for instance, are particularly suitable for use in the polymer matrix. The aromatic polymers can be substantially amorphous, semi-crystalline, or crystalline in nature. One example of a suitable semi-crystalline aromatic polymer, for instance, is an aromatic polyester, which may be a condensation product of at least one diol (e.g., aliphatic and/or cycloaliphatic) with at least one aromatic dicarboxylic acid, such as those having from 4 to 20 carbon atoms, and in some embodiments, from 8 to 14 carbon atoms. Suitable diols may include, for instance, neopentyl glycol, cyclohexanedimethanol, 2,2-dimethyl-1,3-propane diol and aliphatic glycols of the formula HO(CH₂)ₙOH where n is an integer of 2 to 10. Suitable aromatic dicarboxylic acids may include, for instance, isophthalic acid, terephthalic acid, 1,2-di(p-carboxyphenyl)ethane, 4,4′-dicarboxydiphenyl ether, etc., as well as combinations thereof. Fused rings can also be present such as in 1,4- or 1,5- or 2,6-naphthalene-dicarboxylic acids. Particular examples of such aromatic polyesters may include, for instance, poly(ethylene terephthalate) (PET), poly(1,4-butylene terephthalate) (PBT), poly(1,3-propylene terephthalate) (PPT), poly(1,4-butylene 2,6-naphthalate) (PBN), poly(ethylene 2,6-naphthalate) (PEN), poly(1,4-cyclohexylene dimethylene terephthalate) (PCT), as well as mixtures of the foregoing.

Derivatives and/or copolymers of aromatic polyesters (e.g., polyethylene terephthalate) may also be employed. For instance, in one embodiment, a modifying acid and/or diol may be used to form a derivative of such polymers. As used herein, the terms “modifying acid” and “modifying diol” are meant to define compounds that can form part of the acid and diol repeat units of a polyester, respectively, and which can modify a polyester to reduce its crystallinity or render the polyester amorphous. Examples of modifying acid components may include, but are not limited to, isophthalic acid, phthalic acid, 1,3-cyclohexanedicarboxylic acid, 1,4-cyclohexane dicarboxylic acid, 2,6-naphthaline dicarboxylic acid, succinic acid, glutaric acid, adipic acid, sebacic acid, suberic acid, 1,12-dodecanedioic acid, etc. In practice, it is often preferable to use a functional acid derivative thereof such as the dimethyl, diethyl, or dipropyl ester of the dicarboxylic acid. The anhydrides or acid halides of these acids also may be employed where practical. Examples of modifying diol components may include, but are not limited to, neopentyl glycol, 1,4-cyclohexanedimethanol, 1,2-propanediol, 1,3-propanediol, 2-methy-1,3-propanediol, 1,4-butanediol, 1,6-hexanediol, 1,2-cyclohexanediol, 1,4-cyclohexanediol, 1,2-cyclohexanedimethanol, 1,3-cyclohexanedimethanol, 2,2,4,4-tetramethyl 1,3-cyclobutane diol, Z,8-bis(hydroxymethyltricyclo-[5.2.1.0]-decane wherein Z represents 3, 4, or 5; 1,4-bis(2-hydroxyethoxy)benzene, 4,4′-bis(2-hydroxyethoxy) diphenylether [bis-hydroxyethyl bisphenol A], 4,4′-Bis(2-hydroxyethoxy)diphenylsulfide [bis-hydroxyethyl bisphenol S] and diols containing one or more oxygen atoms in the chain, e.g. diethylene glycol, triethylene glycol, dipropylene glycol, tripropylene glycol, etc. In general, these diols contain 2 to 18, and in some embodiments, 2 to 8 carbon atoms. Cycloaliphatic diols can be employed in their cis- or trans-configuration or as mixtures of both forms.

The aromatic polyesters, such as described above, typically have a DTUL value of from about 40° C. to about 80° C., in some embodiments from about 45° C. to about 75° C., and in some embodiments, from about 50° C. to about 70° C. as determined in accordance with ISO 75-2:2013 at a load of 1.8 MPa. The aromatic polyesters likewise typically have a glass transition temperature of from about 30° C. to about 120° C., in some embodiments from about 40° C. to about 110° C., and in some embodiments, from about 50° C. to about 100° C., such as determined by ISO 11357-2:2020, as well as a melting temperature of from about 170° C. to about 300° C., in some embodiments from about 190° C. to about 280° C., and in some embodiments, from about 210° C. to about 260° C., such as determined in accordance with ISO 11357-2:2018. The aromatic polyesters may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-5:1998.

Polyarylene sulfides are also suitable semi-crystalline aromatic polymers. The polyarylene sulfide may be homopolymers or copolymers. For instance, selective combination of dihaloaromatic compounds can result in a polyarylene sulfide copolymer containing not less than two different units. For instance, when p-dichlorobenzene is used in combination with m-dichlorobenzene or 4,4′-dichlorodiphenylsulfone, a polyarylene sulfide copolymer can be formed containing segments having the structure of formula:

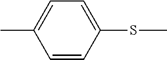

and segments having the structure of formula:

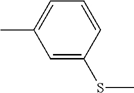

or segments having the structure of formula:

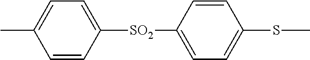

The polyarylene sulfide may be linear, semi-linear, branched or crosslinked. Linear polyarylene sulfides typically contain 80 mol % or more of the repeating unit-(Ar-S)-. Such linear polymers may also include a small amount of a branching unit or a cross-linking unit, but the amount of branching or cross-linking units is typically less than about 1 mol % of the total monomer units of the polyarylene sulfide. A linear polyarylene sulfide polymer may be a random copolymer or a block copolymer containing the above-mentioned repeating unit. Semi-linear polyarylene sulfides may likewise have a cross-linking structure or a branched structure introduced into the polymer a small amount of one or more monomers having three or more reactive functional groups. By way of example, monomer components used in forming a semi-linear polyarylene sulfide can include an amount of polyhaloaromatic compounds having two or more halogen substituents per molecule which can be utilized in preparing branched polymers. Such monomers can be represented by the formula R′Xₙ, where each X is selected from chlorine, bromine, and iodine, n is an integer of 3 to 6, and R′ is a polyvalent aromatic radical of valence n which can have up to about 4 methyl substituents, the total number of carbon atoms in R′ being within the range of 6 to about 16. Examples of some polyhaloaromatic compounds having more than two halogens substituted per molecule that can be employed in forming a semi-linear polyarylene sulfide include 1,2,3-trichlorobenzene, 1,2,4-trichlorobenzene, 1,3-dichloro-5-bromobenzene, 1,2,4-triiodobenzene, 1,2,3,5-tetrabromobenzene, hexachlorobenzene, 1,3,5-trichloro-2,4,6-trimethylbenzene, 2,2′,4,4′-tetrachlorobiphenyl, 2,2′,5,5′-tetra-iodobiphenyl, 2,2′,6,6′-tetrabromo-3,3′,5,5′-tetramethylbiphenyl, 1,2,3,4-tetrachloronaphthalene, 1,2,4-tribromo-6-methylnaphthalene, etc., and mixtures thereof.

The polyarylene sulfides, such as described above, typically have a DTUL value of from about 70° C. to about 220° C., in some embodiments from about 90° C. to about 200° C., and in some embodiments, from about 120° C. to about 180° C. as determined in accordance with ISO 75-2:2013 at a load of 1.8 MPa. The polyarylene sulfides likewise typically have a glass transition temperature of from about 50° C. to about 120° C., in some embodiments from about 60° C. to about 115° C., and in some embodiments, from about 70° C. to about 110° C., such as determined by ISO 11357-2:2020, as well as a melting temperature of from about 220° C. to about 340° C., in some embodiments from about 240° C. to about 320° C., and in some embodiments, from about 260° C. to about 300° C., such as determined in accordance with ISO 11357-3:2018.

As indicated above, substantially amorphous polymers may also be employed that lack a distinct melting point temperature. Suitable amorphous polymers may include, for instance, aromatic polycarbonates, which typically contains repeating structural carbonate units of the formula —R¹—O—C(O)—O—. The polycarbonate is aromatic in that at least a portion (e.g., 60% or more) of the total number of R¹ groups contain aromatic moieties and the balance thereof are aliphatic, alicyclic, or aromatic. In one embodiment, for instance, R¹ may a C₆₋₃₀ aromatic group, that is, contains at least one aromatic moiety. Typically, R¹ is derived from a dihydroxy aromatic compound of the general formula HO—R¹—OH, such as those having the specific formula referenced below:

HO-A¹-Y¹-A²-OH

wherein,

A¹ and A² are independently a monocyclic divalent aromatic group; and

Y¹ is a single bond or a bridging group having one or more atoms that separate A¹ from A². In one particular embodiment, the dihydroxy aromatic compound may be derived from the following formula (I):

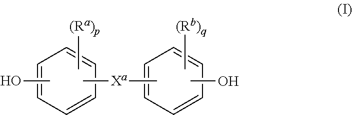

wherein,

R^{a} and R^{b} are each independently a halogen or C₁₋₁₂ alkyl group, such as a C₁₋₃ alkyl group (e.g., methyl) disposed meta to the hydroxy group on each arylene group;

p and q are each independently 0 to 4 (e.g., 1); and

X^{a} represents a bridging group connecting the two hydroxy-substituted aromatic groups, where the bridging group and the hydroxy substituent of each C₆ arylene group are disposed ortho, meta, or para (specifically para) to each other on the C₆ arylene group.

In one embodiment, X^{a} may be a substituted or unsubstituted C₃₋₁₈ cycloalkylidene, a C₁₋₂₅ alkylidene of formula —C(R^{c})(R^{d})— wherein R^{c} and R^{d} are each independently hydrogen, C₁₋₁₂ alkyl, C₁₋₁₂ cycloalkyl, C₇₋₁₂ arylalcyl, C₇₋₁₂ heteroalkyl, or cyclic C₇₋₁₂ heteroarylalkyl, or a group of the formula —C(═R^{e})— wherein R^{e} is a divalent C₁₋₁₂ hydrocarbon group. Exemplary groups of this type include methylene, cyclohexylmethylene, ethylidene, neopentylidene, and isopropylidene, as well as 2-[2.2.1]-bicycloheptylidene, cyclohexylidene, cyclopentylidene, cyclododecylidene, and adamantylidene. A specific example wherein X^{a} is a substituted cycloalkylidene is the cyclohexylidene-bridged, alkyl-substituted bisphenol of the following formula (II):

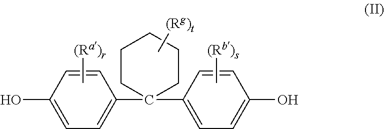

wherein,

R^{a′} and R^{b′} are each independently C₁₋₁₂ alkyl (e.g., C₁₋₄ alkyl, such as methyl), and may optionally be disposed meta to the cyclohexylidene bridging group;

R^{g} is C₁₋₁₂ alkyl (e.g., C₁₋₄ alkyl) or halogen;

r and s are each independently 1 to 4 (e.g., 1); and

t is 0 to 10, such as 0 to 5.

The cyclohexylidene-bridged bisphenol can be the reaction product of two moles of o-cresol with one mole of cyclohexanone. In another embodiment, the cyclohexylidene-bridged bisphenol can be the reaction product of two moles of a cresol with one mole of a hydrogenated isophorone (e.g., 1,1,3-trimethyl-3-cyclohexane-5-one). Such cyclohexane-containing bisphenols, for example the reaction product of two moles of a phenol with one mole of a hydrogenated isophorone, are useful for making polycarbonate polymers with high glass transition temperatures and high heat distortion temperatures.

In another embodiment, X^{a} may be a C₁₋₁₈ alkylene group, a C₃₋₁₈ cycloalkylene group, a fused C₆₋₁₈ cycloalkylene group, or a group of the formula —B¹—W—B²—, wherein B¹ and B² are independently a C₁₋₆ alkylene group and W is a C₃₋₁₂ cycloalkylidene group or a C₆₋₁₆ arylene group.

X^{a} may also be a substituted C₃₋₁₈ cycloalkylidene of the following formula (III):

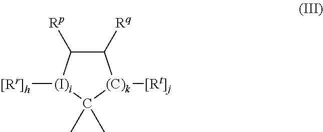

wherein,

R^{r}, R^{p}, R^{q}, and R^{t} are each independently hydrogen, halogen, oxygen, or C₁₋₁₂ organic groups;

I is a direct bond, a carbon, or a divalent oxygen, sulfur, or —N(Z)—, wherein Z is hydrogen, halogen, hydroxy, C₁₋₁₂ alkyl, C₁₋₁₂ alkoxy, or C₁₋₁₂ acyl;

h is 0 to 2;

j is 1 or 2;

i is 0 or 1; and

k is 0 to 3, with the proviso that at least two of R^{r}, R^{p}, R^{q}, and R^{t} taken together are a fused cycloaliphatic, aromatic, or heteroaromatic ring.

Other useful aromatic dihydroxy aromatic compounds include those having the following formula (IV):

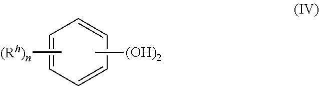

wherein,

R^{h} is independently a halogen atom (e.g., bromine), C₁₋₁₀ hydrocarbyl (e.g., C₁₋₁₀ alkyl group), a halogen-substituted C₁₋₁₀ alkyl group, a C₆₋₁₀ aryl group, or a halogen-substituted C₆₋₁₀ aryl group;

n is 0 to 4.

Specific examples of bisphenol compounds of formula (I) include, for instance, 1,1-bis(4-hydroxyphenyl) methane, 1,1-bis(4-hydroxyphenyl) ethane, 2,2-bis(4-hydroxyphenyl)propane (hereinafter “bisphenol A” or “BPA”), 2,2-bis(4-hydroxyphenyl)butane, 2,2-bis(4-hydroxyphenyl)octane, 1,1-bis(4-hydroxyphenyl)propane, 1,1-bis(4-hydroxyphenyl) n-butane, 2,2-bis(4-hydroxy-1-methylphenyl)propane, 1,1-bis(4-hydroxy-t-butylphenyl)propane, 3,3-bis(4-hydroxyphenyl)phthalimidine, 2-phenyl-3,3-bis(4-hydroxyphenyl)phthalimidine (PPPBP), and 1,1-bis(4-hydroxy-3-methylphenyl)cyclohexane (DMBPC). In one specific embodiment, the polycarbonate may be a linear homopolymer derived from bisphenol A, in which each of A¹ and A² is p-phenylene and Y¹ is isopropylidene in formula (I).

Other examples of suitable aromatic dihydroxy compounds may include, but not limited to, 4,4′-dihydroxybiphenyl, 1,6-dihydroxynaphthalene, 2,6-dihydroxynaphthalene, bis(4-hydroxyphenyl)methane, bis(4-hydroxyphenyl)diphenylmethane, bis(4-hydroxyphenyl)-1-naphthylmethane, 1,2-bis(4-hydroxyphenyl)ethane, 1,1-bis(4-hydroxyphenyl)-1-phenylethane, 2-(4-hydroxyphenyl)-2-(3-hydroxyphenyl)propane, bis(4-hydroxyphenyl)phenylmethane, 2,2-bis(4-hydroxy-3-bromophenyl)propane, 1,1-bis (hydroxyphenyl)cyclopentane, 1,1-bis(4-hydroxyphenyl)cyclohexane, 1,1-bis(4-hydroxyphenyl)isobutene, 1,1-bis(4-hydroxyphenyl)cyclododecane, trans-2,3-bis(4-hydroxyphenyl)-2-butene, 2,2-bis(4-hydroxyphenyl)adamantane, alpha, alpha′-bis(4-hydroxyphenyl)toluene, bis(4-hydroxyphenyl)acetonitrile, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-t-butyl-4-hydroxyphenyl)propane, 2,2-bis(3-cyclohexyl-4-hydroxyphenyl)propane, 2,2-bis(3-allyl-4-hydroxyphenyl)propane, 2,2-bis(3-methoxy-4-hydroxyphenyl)propane, 2,2-bis(4-hydroxyphenyl)hexafluoropropane, 1,1-dichloro-2,2-bis(4-hydroxyphenyl)ethylene, 1,1-dibromo-2,2-bis(4-hydroxyphenyl)ethylene, 1,1-dichloro-2,2-bis(5-phenoxy-4-hydroxyphenyl)ethylene 4,4′-dihydroxybenzophenone, 3,3-bis(4-hydroxyphenyl)-2-butanone, 1,6-bis(4-hydroxyphenyl)-1,6-hexanedione, ethylene glycol bis(4-hydroxyphenyl)ether, bis(4-hydroxyphenyl)ether, bis(4-hydroxyphenyl)sulfide, bis(4-hydroxyphenyl)sulfoxide, bis(4-hydroxyphenyl)sulfone, 9,9-bis(4-hydroxyphenyl)fluorine, 2,7-dihydroxypyrene, 6,6′-dihydroxy-3,3,3′,3′-tetramethylspiro(bis)indane (“spirobiindane bisphenol”), 3,3-bis(4-hydroxyphenyl)phthalimide, 2,6-dihydroxydibenzo-p-dioxin, 2,6-dihydroxythianthrene, 2,7-dihydroxyphenoxathin, 2,7-dihydroxy-9,10-dimethylphenazine, 3,6-dihydroxydibenzofuran, 3,6-dihydroxydibenzothiophene, and 2,7-dihydroxycarbazole, resorcinol, substituted resorcinol compounds such as 5-methyl resorcinol, 5-ethyl resorcinol, 5-propyl resorcinol, 5-butyl resorcinol, 5-t-butyl resorcinol, 5-phenyl resorcinol, 5-cumyl resorcinol, 2,4,5,6-tetrafluoro resorcinol, 2,4,5,6-tetrabromo resorcinol, or the like; catechol; hydroquinone; substituted hydroquinones such as 2-methyl hydroquinone, 2-ethyl hydroquinone, 2-propyl hydroquinone, 2-butyl hydroquinone, 2-t-butyl hydroquinone, 2-phenyl hydroquinone, 2-cumyl hydroquinone, 2,3,5,6-tetramethyl hydroquinone, 2,3,5,6-tetra-t-butyl hydroquinone, 2,3,5,6-tetrafluoro hydroquinone, 2,3,5,6-tetrabromo hydroquinone, etc., as well as combinations thereof.

Aromatic polycarbonates, such as described above, typically have a DTUL value of from about 80° C. to about 300° C., in some embodiments from about 100° C. to about 250° C., and in some embodiments, from about 140° C. to about 220° C., as determined in accordance with ISO 75-2:2013 at a load of 1.8 MPa. The glass transition temperature may also be from about 50° C. to about 250° C., in some embodiments from about 90° C. to about 220° C., and in some embodiments, from about 100° C. to about 200° C., such as determined by ISO 11357-2:2020. Such polycarbonates may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-4:1998.

In addition to the polymers referenced above, highly crystalline aromatic polymers may also be employed in the polymer composition. Particularly suitable examples of such polymers are liquid crystalline polymers, which have a high degree of crystallinity that enables them to effectively fill the small spaces of a mold. Liquid crystalline polymers are generally classified as “thermotropic” to the extent that they can possess a rod-like structure and exhibit a crystalline behavior in their molten state (e.g., thermotropic nematic state). Such polymer typically have a DTUL value of from about 120° C. to about 340° C., in some embodiments from about 140° C. to about 320° C., and in some embodiments, from about 150° C. to about 300° C., as determined in accordance with ISO 75-2:2013 at a load of 1.8 MPa. The polymers also have a relatively high melting temperature, such as from about 250° C. to about 400° C., in some embodiments from about 280° C. to about 390° C., and in some embodiments, from about 300° C. to about 380° C. Such polymers may be formed from one or more types of repeating units as is known in the art.

A liquid crystalline polymer may, for example, contain one or more aromatic ester repeating units, typically in an amount of from about 60 mol. % to about 99.9 mol. %, in some embodiments from about 70 mol. % to about 99.5 mol. %, and in some embodiments, from about 80 mol. % to about 99 mol. % of the polymer. The aromatic ester repeating units may be generally represented by the following Formula (V):

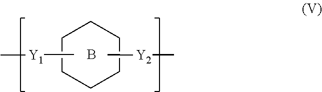

wherein,

ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and

Y₁ and Y₂ are independently O, C(O), NH, C(O)HN, or NHC(O).

Typically, at least one of Y₁ and Y₂ are C(O). Examples of such aromatic ester repeating units may include, for instance, aromatic dicarboxylic repeating units (Y₁ and Y₂ in Formula V are C(O)), aromatic hydroxycarboxylic repeating units (Y₁ is O and Y₂ is C(O) in Formula V), as well as various combinations thereof.

Aromatic dicarboxylic repeating units, for instance, may be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”), isophthalic acid (“IA”), and 2,6-naphthalenedicarboxylic acid (“NDA”). When employed, repeating units derived from aromatic dicarboxylic acids (e.g., IA, TA, and/or NDA) typically constitute from about 5 mol. % to about 60 mol. %, in some embodiments from about 10 mol. % to about 55 mol. %, and in some embodiments, from about 15 mol. % to about 50% of the polymer.

Aromatic hydroxycarboxylic repeating units may also be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 4-hydroxybenzoic acid (“HBA”) and 6-hydroxy-2-naphthoic acid (“HNA”). When employed, repeating units derived from hydroxycarboxylic acids (e.g., HBA and/or HNA) typically constitute from about 10 mol. % to about 85 mol. %, in some embodiments from about 20 mol. % to about 80 mol. %, and in some embodiments, from about 25 mol. % to about 75% of the polymer.

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) typically constitute from about 1 mol. % to about 30 mol. %, in some embodiments from about 2 mol. % to about 25 mol. %, and in some embodiments, from about 5 mol. % to about 20% of the polymer. Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) typically constitute from about 0.1 mol. % to about 20 mol. %, in some embodiments from about 0.5 mol. % to about 15 mol. %, and in some embodiments, from about 1 mol. % to about 10% of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids, diols, amides, amines, etc. Of course, in other embodiments, the polymer may be “wholly aromatic” in that it lacks repeating units derived from non-aromatic (e.g., aliphatic or cycloaliphatic) monomers.

In one particular embodiment, the liquid crystalline polymer may be formed from repeating units derived from 4-hydroxybenzoic acid (“HBA”) and terephthalic acid (“TA”) and/or isophthalic acid (“IA”), as well as various other optional constituents. The repeating units derived from 4-hydroxybenzoic acid (“HBA”) may constitute from about 10 mol. % to about 80 mol. %, in some embodiments from about 30 mol. % to about 75 mol. %, and in some embodiments, from about 45 mol. % to about 70% of the polymer. The repeating units derived from terephthalic acid (“TA”) and/or isophthalic acid (“IA”) may likewise constitute from about 5 mol. % to about 40 mol. %, in some embodiments from about 10 mol. % to about 35 mol. %, and in some embodiments, from about 15 mol. % to about 35% of the polymer. Repeating units may also be employed that are derived from 4,4′-biphenol (“BP”) and/or hydroquinone (“HQ”) in an amount from about 1 mol. % to about 30 mol. %, in some embodiments from about 2 mol. % to about 25 mol. %, and in some embodiments, from about 5 mol. % to about 20% of the polymer. Other possible repeating units may include those derived from 6-hydroxy-2-naphthoic acid (“HNA”), 2,6-naphthalenedicarboxylic acid (“NDA”), and/or acetaminophen (“APAP”). In certain embodiments, for example, repeating units derived from HNA, NDA, and/or APAP may each constitute from about 1 mol. % to about 35 mol. %, in some embodiments from about 2 mol. % to about 30 mol. %, and in some embodiments, from about 3 mol. % to about 25 mol. % when employed.

Of course, besides aromatic polymers, aliphatic polymers may also be suitable for use as high performance, thermoplastic polymers in the polymer matrix. In one embodiment, for instance, polyamides may be employed that generally have a CO—NH linkage in the main chain and are obtained by condensation of an aliphatic diamine and an aliphatic dicarboxylic acid, by ring opening polymerization of lactam, or self-condensation of an amino carboxylic acid. For example, the polyamide may contain aliphatic repeating units derived from an aliphatic diamine, which typically has from 4 to 14 carbon atoms. Examples of such diamines include linear aliphatic alkylenediamines, such as 1,4-tetramethylenediamine, 1,6-hexanediamine, 1,7-heptanediamine, 1,8-octanediamine, 1,9-nonanediamine, 1,10-decanediamine, 1,11-undecanediamine, 1,12-dodecanediamine, etc.; branched aliphatic alkylenediamines, such as 2-methyl-1,5-pentanediamine, 3-methyl-1,5 pentanediamine, 2,2,4-trimethyl-1,6-hexanediamine, 2,4,4-trimethyl-1,6-hexanediamine, 2,4-dimethyl-1,6-hexanediamine, 2-methyl-1,8-octanediamine, 5-methyl-1,9-nonanediamine, etc.; as well as combinations thereof. Aliphatic dicarboxylic acids may include, for instance, adipic acid, sebacic acid, etc. Particular examples of such aliphatic polyamides include, for instance, nylon-4 (poly-α-pyrrolidone), nylon-6 (polycaproamide), nylon-11 (polyundecanamide), nylon-12 (polydodecanamide), nylon-46 (polytetramethylene adipamide), nylon-66 (polyhexamethylene adipamide), nylon-610, and nylon-612. Nylon-6 and nylon-66 are particularly suitable.

It should be understood that it is also possible to include aromatic monomer units in the polyamide such that it is considered aromatic (contains only aromatic monomer units are both aliphatic and aromatic monomer units). Examples of aromatic dicarboxylic acids may include, for instance, terephthalic acid, isophthalic acid, 2,6-naphthalenedicarboxylic acid, 2,7-naphthalenedicarboxylic acid, 1,4-naphthalenedicarboxylic acid, 1,4-phenylenedioxy-diacetic acid, 1,3-phenylenedioxy-diacetic acid, diphenic acid, 4,4′-oxydibenzoic acid, diphenylmethane-4,4′-dicarboxylic acid, diphenylsulfone-4,4′-dicarboxylic acid, 4,4′-biphenyldicarboxylic acid, etc. Particularly suitable aromatic polyamides may include poly(nonamethylene terephthalamide) (PA9T), poly(nonamethylene terephthalamide/nonamethylene decanediamide) (PA9T/910), poly(nonamethylene terephthalamide/nonamethylene dodecanediamide) (PA9T/912), poly(nonamethylene terephthalamide/11-aminoundecanamide) (PA9T/11), poly(nonamethylene terephthalamide/12-aminododecanamide) (PA9T/12), poly(decamethylene terephthalamide/11-aminoundecanamide) (PA10T/11), poly(decamethylene terephthalamide/12-aminododecanamide) (PA10T/12), poly(decamethylene terephthalamide/decamethylene decanediamide) (PA10T/1010), poly(decamethylene terephthalamide/decamethylene dodecanediamide) (PA10T/1012), poly(decamethylene terephlhalamide/tetramethylene hexanediamide) (PA10T/46), poly(decamethylene terephthalamide/caprolactam) (PA10T/6), poly(decamethylene terephthalamide/hexamethylene hexanediamide) (PA10T/66), poly(dodecamethylene lerephthalamide/dodecamelhylene dodecanediarnide) (PA12T/1212), poly(dodecamethylene terephthalamide/caprolactam) (PA12T/6), poly(dodecamethylene terephthalamide/hexamethylene hexanediamide) (PA12T/66), and so forth.

The polyamide employed in the polyamide composition is typically crystalline or semi-crystalline in nature and thus has a measurable melting temperature. The melting temperature may be relatively high such that the composition can provide a substantial degree of heat resistance to a resulting part. For example, the polyamide may have a melting temperature of about 220° C. or more, in some embodiments from about 240° C. to about 325° C., and in some embodiments, from about 250° C. to about 335° C. The polyamide may also have a relatively high glass transition temperature, such as about 30° C. or more, in some embodiments about 40° C. or more, and in some embodiments, from about 45° C. to about 140° C. The glass transition and melting temperatures may be determined as is well known in the art using differential scanning calorimetry (“DSC”), such as determined by ISO Test No. 11357-2:2020 (glass transition) and 11357-3:2018 (melting).

Propylene polymers may also be suitable aliphatic high performance polymers for use in the polymer matrix. Any of a variety of propylene polymers or combinations of propylene polymers may generally be employed in the polymer matrix, such as propylene homopolymers (e.g., syndiotactic, atactic, isotactic, etc.), propylene copolymers, and so forth. In one embodiment, for instance, a propylene polymer may be employed that is an isotactic or syndiotactic homopolymer. The term “syndiotactic” generally refers to a tacticity in which a substantial portion, if not all, of the methyl groups alternate on opposite sides along the polymer chain. On the other hand, the term “isotactic” generally refers to a tacticity in which a substantial portion, if not all, of the methyl groups are on the same side along the polymer chain. In yet other embodiments, a copolymer of propylene with an α-olefin monomer may be employed. Specific examples of suitable α-olefin monomers may include ethylene, 1-butene; 3-methyl-1-butene; 3,3-dimethyl-1-butene; 1-pentene; 1-pentene with one or more methyl, ethyl or propyl substituents; 1-hexene with one or more methyl, ethyl or propyl substituents; 1-heptene with one or more methyl, ethyl or propyl substituents; 1-octene with one or more methyl, ethyl or propyl substituents; 1-nonene with one or more methyl, ethyl or propyl substituents; ethyl, methyl or dimethyl-substituted 1-decene; 1-dodecene; and styrene. The propylene content of such copolymers may be from about 60 mol. % to about 99 mol. %, in some embodiments from about 80 mol. % to about 98.5 mol. %, and in some embodiments, from about 87 mol. % to about 97.5 mol. %. The α-olefin content may likewise range from about 1 mol. % to about 40 mol. %, in some embodiments from about 1.5 mol. % to about 15 mol. %, and in some embodiments, from about 2.5 mol. % to about 13 mol. %.

Suitable propylene polymers are typically those having a DTUL value of from about 80° C. to about 250° C., in some embodiments from about 100° C. to about 220° C., and in some embodiments, from about 110° C. to about 200° C., as determined in accordance with ISO 75-2:2013 at a load of 1.8 MPa. The glass transition temperature of such polymers may likewise be from about 10° C. to about 80° C., in some embodiments from about 15° C. to about 70° C., and in some embodiments, from about 20° C. to about 60° C., such as determined by ISO 11357-2:2020. Further, the melting temperature of such polymers may be from about 50° C. to about 250° C., in some embodiments from about 90° C. to about 220° C., and in some embodiments, from about 100° C. to about 200° C., such as determined by ISO 11357-3:2018.

Oxymethylene polymers may also be suitable aliphatic high performance polymers for use in the polymer matrix. Oxymethylene polymers can be either one or more homopolymers, copolymers, or a mixture thereof. Homopolymers are prepared by polymerizing formaldehyde or formaldehyde equivalents, such as cyclic oligomers of formaldehyde. Copolymers can contain one or more comonomers generally used in preparing polyoxymethylene compositions. Commonly used comonomers include alkylene oxides of 2-12 carbon atoms. If a copolymer is selected, the quantity of comonomer will typically not be more than 20 weight percent, in some embodiments not more than 15 weight percent, and, in some embodiments, about two weight percent.

Comonomers can include ethylene oxide and butylene oxide. It is preferred that the homo- and copolymers are: 1) those whose terminal hydroxy groups are end-capped by a chemical reaction to form ester or ether groups; or, 2) copolymers that are not completely end-capped, but that have some free hydroxy ends from the comonomer unit. Typical end groups, in either case, are acetate and methoxy.

B. EMI Filler

As indicated above, an EMI filler is also distributed within the polymer matrix. The EMI filler is generally formed from an electrically conductive material that can provide the desired degree of electromagnetic interference shielding. In certain embodiments, for instance, the material may contain a metal, such as stainless steel, aluminum, zinc, iron, copper, silver, nickel, gold, chrome, etc., as well alloys or mixtures thereof; carbon (e.g., carbon fibers, carbon particles, such as graphite, carbon nanotubes, carbon black, etc.); and so forth). The EMI filler may also possess a variety of different forms, such as particles (e.g., iron powder), flakes (e.g., aluminum flakes, stainless steel flakes, etc.), or fibers.

The EMI filler may, for instance, include fibers. The fibers may have a high degree of tensile strength relative to their mass. For example, the tensile strength of the fibers is typically from about 500 to about 10,000 MPa, in some embodiments from about 600 MPa to about 4,000 MPa, and in some embodiments, from about 800 MPa to about 2,000 MPa, such as determined in accordance with ASTM D4018-17. The fibers may have an average diameter of from about 1 to about 200 micrometers, in some embodiments from about 1 to about 150 micrometers, in some embodiments from about 3 to about 100 micrometers, and in some embodiments, from about 5 to about 50 micrometers. The fibers may be continuous filaments, chopped, or milled. In certain embodiments, for instance, the fibers may be chopped fibers having a volume average length of the fibers may likewise range from about 0.1 to about 15 millimeters, in some embodiments from about 0.5 to about 12 millimeters, and in some embodiments, from about 1 to about 10 millimeters.

In certain embodiments, the fibers may include a metal, such as being formed primarily from the metal (e.g., stainless steel fibers) or from a core material that is coated with the metal. When employing a metal coating, the core material may be formed from a material that is either conductive or insulative in nature. For example, the core material may be formed from carbon, glass, or a polymer. One example of such a fiber is nickel-coated carbon fibers. The EMI filler may also include fibers that contain a carbon material. When employed, such carbon fibers may exhibit a high intrinsic thermal conductivity, such as about 200 W/m-k or more, in some embodiments about 500 W/m-K or more, in some embodiments from about 600 W/m-K to about 3,000 W/m-K, and in some embodiments, from about 800 W/m-K to about 1,500 W/m-K, as well as a low intrinsic electrical resistivity (single filament) of less than about 20 μohm-m, in some embodiments less than about 10 μoh-m, in some embodiments from about 0.05 to about 5 μohm-m, and in some embodiments, from about 0.1 to about 2 μohm-m. The nature of the carbon fibers may vary, such as carbon fibers obtained from cellulose, lignin, polyacrylonitrile (PAN) and pitch. Pitch-based carbon fibers are particularly suitable for use in the polymer composition. Such pitch-based fibers may, for instance, be derived from condensation polycyclic hydrocarbon compounds (e.g., naphthalene, phenanthrene, etc.), condensation heterocyclic compounds (e.g., petroleum-based pitch, coal-based pitch, etc.), and so forth. It may be particularly desirable to employ an optically anisotropic pitch (“mesophase pitch”) as such pitch can form a thermotropic crystal, which allows the pitch to become organized and form linear chains, thereby resulting in fibers that are more sheet-like in nature due to their crystal structure. Among other things, fibers having such a morphology may possess a higher degree of intrinsic thermal conductivity. The mesophase pitch typically contains greater than 90 wt. % mesophase, and in some embodiments, approximately 100 wt. % mesophase pitch, as defined and described by the terminology and methods disclosed by S. Chwastiak et al in Carbon 19, 357-363 (1981). Such pitch-based carbon fibers may be formed using any of a variety of techniques known in the art. For example, the pitch-based fibers may be formed by melt spinning a high purity mesophase pitch at a temperature above the softening point of the raw pitch material, such as about 250° C. or more, and in some embodiments, from about 250° C. to about 350° C. The melt spun fibers may then be subjected to a variety of heat treatment steps to remove impurities, such as oxidization/pre-carbonization to initiate crosslinking and remove impurities, carbonization to remove inorganic elements, and/or graphitization improve alignment and orientation of the crystalline regions. Such heat treatment steps generally occur at a high temperature, such as from about 400° C. to about 2,500° C., and in an inert atmosphere. Examples of such techniques are described, for instance, in U.S. Pat. No. 8,642,682 to Nishihata, et al. and U.S. Pat. No. 7,846,543 to Sano, et al.

The EMI filler is typically present in an amount of from about 1 wt. % to about 70 wt. %, in some embodiments from about 1.5 wt. % to about 65 wt. %, and in some embodiments, from about 4 wt. % to about 60 wt. % of the composition. Of course, the exact amount of the EMI filler will generally depend on the nature of the filler (e.g., conductivity) as well as the nature of other components in the composition. For example, when employing highly conductive EMI fillers, such as those formed containing a metal (e.g., stainless steel), a relatively low amount of the EMI filler may be employed, such as from about 1 wt. % to about 40 wt. %, in some embodiments from about 2 wt. % to about 30 wt. %, and in some embodiments, from about 4 wt. % to about 20 wt. % of the composition. Likewise, when employing EMI fillers having a relatively low degree of conductivity, such as those containing a carbon material (e.g., carbon fibers or carbon particles), a relatively high amount of the EMI filler may be employed, such as from about 10 wt. % to about 70 wt. %, in some embodiments from about 20 wt. % to about 65 wt. %, and in some embodiments, from about 30 wt. % to about 60 wt. % of the composition.

If desired, the EMI filler and other components as described below (e.g., thermally conductive fillers, flame retardants, stabilizers, reinforcing fibers, pigments, lubricants, etc.) may be melt blended together to form the polymer matrix. The raw materials may be supplied either simultaneously or in sequence to a melt-blending device that dispersively blends the materials. Batch and/or continuous melt blending techniques may be employed. For example, a mixer/kneader, Banbury mixer, Farrel continuous mixer, single-screw extruder, twin-screw extruder, roll mill, etc., may be utilized to blend the materials. One particularly suitable melt-blending device is a co-rotating, twin-screw extruder (e.g., ZSK-30 twin-screw extruder available from Werner & Pfleiderer Corporation of Ramsey, N.J.). Such extruders may include feeding and venting ports and provide high intensity distributive and dispersive mixing.

In certain embodiments, however, the EMI filler may be combined with the polymer matrix using other techniques. In one particular embodiment, for example, the EMI filler may be in the form of “long fibers”, which generally refers to fibers, filaments, yarns, or rovings (e.g., bundles of fibers) that are not continuous and have a length of from about 1 to about 25 millimeters, in some embodiments, from about 1.5 to about 20 millimeters, in some embodiments from about 2 to about 15 millimeters, and in some embodiments, from about 3 to about 12 millimeters. The nominal diameter of the fibers (e.g., diameter of fibers within a roving) may range from about 1 to about 40 micrometers, in some embodiments from about 2 to about 30 micrometers, and in some embodiments, from about 5 to about 25 micrometers. If desired, the fibers may be in the form of rovings (e.g., bundle of fibers) that contain a single fiber type or different types of fibers. The number of fibers contained in each roving can be constant or vary from roving to roving. Typically, a roving may contain from about 1,000 fibers to about 50,000 individual fibers, and in some embodiments, from about 2,000 to about 40,000 fibers.

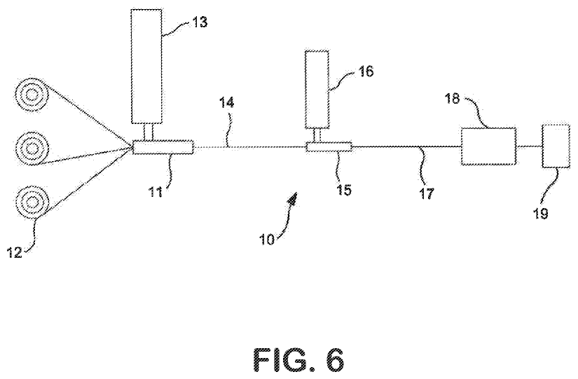

Any of a variety of different techniques may generally be employed to incorporate such long fibers into the polymer matrix. The long fibers may be randomly distributed within the polymer matrix, or alternatively distributed in an aligned fashion. In one embodiment, for instance, continuous fibers may initially be impregnated into the polymer matrix to form strands, which are thereafter cooled and then chopped into pellets to that the resulting fibers have the desired length for the long fibers. In such embodiments, the polymer matrix and continuous fibers (e.g., rovings) are typically pultruded through an impregnation die to achieve the desired contact between the fibers and the polymer. Pultrusion can also help ensure that the fibers are spaced apart and aligned in the same or a substantially similar direction, such as a longitudinal direction that is parallel to a major axis of the pellet (e.g., length), which further enhances the mechanical properties. Referring to FIG. 6, for instance, one embodiment of a pultrusion process 10 is shown in which a polymer matrix is supplied from an extruder 13 to an impregnation die 11 while continuous fibers 12 are a pulled through the die 11 via a puller device 18 to produce a composite structure 14. Typical puller devices may include, for example, caterpillar pullers and reciprocating pullers. While optional, the composite structure 14 may also be pulled through a coating die 15 that is attached to an extruder 16 through which a coating resin is applied to form a coated structure 17. As shown in FIG. 6, the coated structure 17 is then pulled through the puller assembly 18 and supplied to a pelletizer 19 that cuts the structure 17 into the desired size for forming the long fiber-reinforced composition.

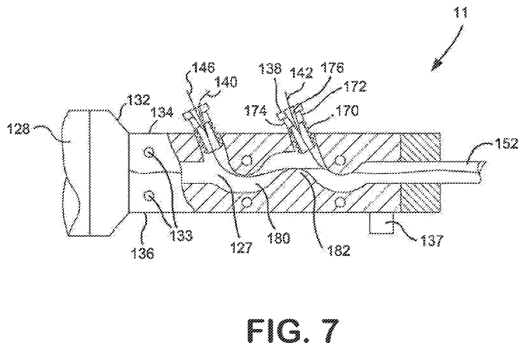

The nature of the impregnation die employed during the pultrusion process may be selectively varied to help achieved good contact between the polymer matrix and the long fibers. Examples of suitable impregnation die systems are described in detail in Reissue Pat. No. 32,772 to Hawley; U.S. Pat. No. 9,233,486 to Regan, et al.; and U.S. Pat. No. 9,278,472 to Eastep, et al. Referring to FIG. 7, for instance, one embodiment of such a suitable impregnation die 11 is shown. As shown, a polymer matrix 127 may be supplied to the impregnation die 11 via an extruder (not shown). More particularly, the polymer matrix 127 may exit the extruder through a barrel flange 128 and enter a die flange 132 of the die 11. The die 11 contains an upper die half 134 that mates with a lower die half 136. Continuous fibers 142 (e.g., roving) are supplied from a reel 144 through feed port 138 to the upper die half 134 of the die 11. Similarly, continuous fibers 146 are also supplied from a reel 148 through a feed port 140. The matrix 127 is heated inside die halves 134 and 136 by heaters 133 mounted in the upper die half 134 and/or lower die half 136. The die is generally operated at temperatures that are sufficient to cause melting and impregnation of the thermoplastic polymer. Typically, the operation temperature of the die is higher than the melt temperature of the polymer matrix. When processed in this manner, the continuous fibers 142 and 146 become embedded in the matrix 127. The mixture is then pulled through the impregnation die 11 to create a fiber-reinforced composition 152. If desired, a pressure sensor 137 may also sense the pressure near the impregnation die 11 to allow control to be exerted over the rate of extrusion by controlling the rotational speed of the screw shaft, or the federate of the feeder.

Within the impregnation die, it is generally desired that the fibers contact a series of impingement zones. At these zones, the polymer melt may flow transversely through the fibers to create shear and pressure, which significantly enhances the degree of impregnation. This is particularly useful when forming a composite from ribbons of a high fiber content. Typically, the die will contain at least 2, in some embodiments at least 3, and in some embodiments, from 4 to 50 impingement zones per roving to create a sufficient degree of shear and pressure. Although their particular form may vary, the impingement zones typically possess a curved surface, such as a curved lobe, rod, etc. The impingement zones are also typically made of a metal material.

FIG. 7 shows an enlarged schematic view of a portion of the impregnation die 11 containing multiple impingement zones in the form of lobes 182. It should be understood that this invention can be practiced using a plurality of feed ports, which may optionally be coaxial with the machine direction. The number of feed ports used may vary with the number of fibers to be treated in the die at one time and the feed ports may be mounted in the upper die half 134 or the lower die half 136. The feed port 138 includes a sleeve 170 mounted in upper die half 134. The feed port 138 is slidably mounted in a sleeve 170. The feed port 138 is split into at least two pieces, shown as pieces 172 and 174. The feed port 138 has a bore 176 passing longitudinally therethrough. The bore 176 may be shaped as a right cylindrical cone opening away from the upper die half 134. The fibers 142 pass through the bore 176 and enter a passage 180 between the upper die half 134 and lower die half 136. A series of lobes 182 are also formed in the upper die half 134 and lower die half 136 such that the passage 210 takes a convoluted route. The lobes 182 cause the fibers 142 and 146 to pass over at least one lobe so that the polymer matrix inside the passage 180 thoroughly contacts each of the fibers. In this manner, thorough contact between the molten polymer and the fibers 142 and 146 is assured.

To further facilitate impregnation, the fibers may also be kept under tension while present within the impregnation die. The tension may, for example, range from about 5 to about 300 Newtons, in some embodiments from about 50 to about 250 Newtons, and in some embodiments, from about 100 to about 200 Newtons per tow of fibers. Furthermore, the fibers may also pass impingement zones in a tortuous path to enhance shear. For example, in the embodiment shown in FIG. 7, the fibers traverse over the impingement zones in a sinusoidal-type pathway. The angle at which the rovings traverse from one impingement zone to another is generally high enough to enhance shear, but not so high to cause excessive forces that will break the fibers. Thus, for example, the angle may range from about 1° to about 30°, and in some embodiments, from about 5° to about 25°.

The impregnation die shown and described above is but one of various possible configurations that may be employed in the present invention. In alternative embodiments, for example, the fibers may be introduced into a crosshead die that is positioned at an angle relative to the direction of flow of the polymer melt. As the fibers move through the crosshead die and reach the point where the polymer exits from an extruder barrel, the polymer is forced into contact with the fibers. It should also be understood that any other extruder design may also be employed, such as a twin screw extruder. Still further, other components may also be optionally employed to assist in the impregnation of the fibers. For example, a “gas jet” assembly may be employed in certain embodiments to help uniformly spread a bundle or tow of individual fibers, which may each contain up to as many as 24,000 fibers, across the entire width of the merged tow. This helps achieve uniform distribution of strength properties in the ribbon. Such an assembly may include a supply of compressed air or another gas that impinges in a generally perpendicular fashion on the moving fiber tows that pass across the exit ports. The spread fiber bundles may then be introduced into a die for impregnation, such as described above.

Other ingredients as referenced below, such as the thermally conductive fillers, reinforcing fibers, stabilizers, antioxidants, lubricants, etc., may also be incorporated into the composition in combination with the long fibers. In the embodiment shown in FIG. 7, for instance, such components may be previously combined with the polymer to form the polymer matrix 127. Alternatively, additional components may also be incorporated into the polymer matrix during fiber impregnation. Notwithstanding these options, a particularly effective technique for incorporating additional components into the polymer matrix involves the use of polymer masterbatches, which are then later combined to form the final composition to allow for better enhanced blending of the components. For example, a first masterbatch (e.g., pellet, strand, etc.) may be formed that a high percentage of long fibers. For example, long fibers may constitute from about 20 wt. % to about 70 wt. %, and in some embodiments, from about 40 wt. % to about 60 wt. % of the first masterbatch, and polymer(s) may constitute from about 20 wt. % to about 70 wt. %, and in some embodiments, from about 40 wt. % to about 60 wt. % of the first masterbatch. A second masterbatch (e.g., pellet, strand, etc.) may also be employed that is generally free of long fibers and that contains substantially all of the additional component(s) employed in the composition. For example, long fibers may constitute no more than about 10 wt. %, and in some embodiments, from 0 wt. % to about 5 wt. % of the second masterbatch. Likewise, the additional component(s) may constitute from about 10 wt. % to about 40 wt. %, and in some embodiments, from about 20 wt. % to about 30 wt. % of the second masterbatch, and polymer(s) may constitute from about 20 wt. % to about 70 wt. %, and in some embodiments, from about 40 wt. % to about 60 wt. % of the first masterbatch.

Once formed, the first masterbatch may then be combined with the second masterbatch. For example, the masterbatches may be supplied separately or in combination to an extruder that includes at least one screw rotatably mounted and received within a barrel (e.g., cylindrical barrel) and may define a feed section and a melting section located downstream from the feed section along the length of the screw. One or more of the sections of the extruder are typically heated, such as within a temperature range of from about 200° C. to about 450° C., in some embodiments, from about 210° C. to about 350° C., and in some embodiments, from about 220° C. to about 350° C. to form the composition. The speed of the screw may be selected to achieve the desired residence time, shear rate, melt processing temperature, etc. For example, the screw speed may range from about 50 to about 800 revolutions per minute (“rpm”), in some embodiments from about 70 to about 150 rpm, and in some embodiments, from about 80 to about 120 rpm. The apparent shear rate during melt blending may also range from about 100 seconds⁻¹ to about 10,000 seconds⁻¹, in some embodiments from about 500 seconds⁻¹ to about 5000 seconds⁻¹, and in some embodiments, from about 800 seconds⁻¹ to about 1200 seconds⁻¹. The apparent shear rate is equal to 4Q/πR³, where Q is the volumetric flow rate (“m³/s”) of the polymer melt and R is the radius (“m”) of the capillary (e.g., extruder die) through which the melted polymer flows.

C. Other Components

In addition to the components noted above, the polymer matrix may also contain a variety of other components. Examples of such optional components may include, for instance, thermally conductive fillers, reinforcing fibers, impact modifiers, compatibilizers, particulate fillers (e.g., talc, mica, etc.), stabilizers (e.g., antioxidants, UV stabilizers, etc.), flame retardants, lubricants, colorants, flow modifiers, pigments, and other materials added to enhance properties and processability.

In one embodiment, for example, a thermally conductive filler may be distributed within the polymer matrix, typically in an amount from about 5 wt. % to about 40 wt. %, in some embodiments from about 10 wt. % to about 35 wt. %, and in some embodiments, from about 15 wt. % to about 30 wt. % of the composition. The thermally conductive filler may have a high intrinsic thermal conductivity, such as about 50 W/m-K or more, in some embodiments about 100 W/m-K or more, and in some embodiments, about 150 W/m-K or more. Examples of such materials may include, for instance, boron nitride (BN), aluminum nitride (AlN), magnesium silicon nitride (MgSiN₂), graphite (e.g., expanded graphite), silicon carbide (SiC), carbon nanotubes, carbon black, metal oxides (e.g., zinc oxide, magnesium oxide, beryllium oxide, zirconium oxide, yttrium oxide, etc.), metallic powders (e.g., aluminum, copper, bronze, brass, etc.), etc., as well as combinations thereof. Graphite is particularly suitable for use in the composition of the present invention. In fact, in certain embodiments, graphite may constitute a majority of the thermally conductive filler employed in the polymer composition, such as about 50 wt. % or more, in some embodiments, about 70 wt. % or more, and in some embodiments, from about 90 wt. % to 100 wt. % (e.g., 100 wt. %) of the thermally conductive filler.

The thermally conductive filler may be provided in various forms, such as particulate materials, fibers, etc. For instance, particulate materials may be employed that have an average size (e.g., diameter or length) in the range of about 1 to about 100 micrometers, in some embodiments from about 2 to about 80 micrometers, and in some embodiments, from about 5 to about 60 micrometers, such as determined using laser diffraction techniques in accordance with ISO 13320:2009 (e.g., with a Horiba LA-960 particle size distribution analyzer). In certain embodiments, the particulate material may have a “flake” shape in that it has a relatively high aspect ratio (e.g., average length or diameter divided by average thickness), such as about 4:1 or more, in some embodiments about 8:1 or more, and in some embodiments, from about 10:1 to about 2000:1. The average thickness may, for instance, be about 10 micrometers or less, in some embodiments from about 0.01 micrometers to about 8 micrometers, and in some embodiments, from about 0.05 micrometers to about 5 micrometers. In certain embodiments, the thermally conductive particulate material may be in the form of individual platelets having the desired size. Nevertheless, agglomerates of the thermally conductive material having the desired average size noted above may also be suitable. Such agglomerates generally contain individual particles that are aggregated together with no particular orientation or in a highly ordered fashion, for instance via weak chemical bonds such as Van der Waals forces. Examples of suitable hexagonal boron nitride agglomerates, for instance, include those commercially under the designations UHP-2 (Showa Denko) and PT-450 (Momentive Performance Materials). The thermally conductive particulate material may also have a high specific surface area. The specific surface area may be, for example, about 0.5 m²/g or more, in some embodiments about 1 m²/g or more, and in some embodiments, from about 2 to about 40 m²/g. The specific surface area can be determined according to standard methods such as by the physical gas adsorption method (B.E.T. method) with nitrogen as the adsorption gas, as is generally known in the art and described by Brunauer, Emmet, and Teller (J. Amer. Chem. Soc., vol. 60, February, 1938, pp. 309-319). The particulate material may also have a powder tap density of from about 0.2 to about 1.0 g/cm³, in some embodiments from about 0.3 to about 0.9 g/cm³, and in some embodiments, from about 0.4 to about 0.8 g/cm³, such as determined in accordance with ASTM B527-15.

Reinforcing fibers may also be employed to help improve the mechanical properties. To help maintain an insulative property, which is often desirable for use in electronic components, the reinforcing fibers may be formed from materials that are also generally insulative in nature, such as glass, ceramics (e.g., alumina or silica), aramids (e.g., Kevlar®), polyolefins, polyesters, etc., as well as mixtures thereof. Glass fibers are particularly suitable, such as E-glass, A-glass, C-glass, D-glass, AR-glass, R-glass, S1-glass, S2-glass, etc., and mixtures thereof. The reinforcing fibers may be in the form of randomly distributed fibers, such as when such fibers are melt blended with the high performance polymer(s) during the formation of the polymer matrix. Alternatively, the reinforcing fibers may be in the form of long fibers and impregnated with the polymer matrix in a manner such as described above. Regardless, the volume average length of the reinforcing fibers may be from about 1 to about 400 micrometers, in some embodiments from about 50 to about 400 micrometers, in some embodiments from about 80 to about 250 micrometers, in some embodiments from about 100 to about 200 micrometers, and in some embodiments, from about 110 to about 180 micrometers. The fibers may also have an average diameter of about 10 to about 35 micrometers, and in some embodiments, from about 15 to about 30 micrometers. When employed, the reinforcing fibers typically constitute from about 1 wt. % to about 25 wt. %, in some embodiments from about 2 wt. % to about 20 wt. %, and in some embodiments, from about 5 wt. % to about 15 wt. % of the composition.

Impact modifiers may also help improve the overall properties of the composition. In one embodiment, for instance, a polybutadiene may be employed as a compatibilizer in combination with a high performance polymer (e.g., aromatic polycarbonate) to help improve flexibility. When such a blend is employed, the high performance polymer(s) may, for example, constitute from about 40 wt. % to about 95 wt. %, in some embodiments from about 60 wt. % to about 92 wt. %, and in some embodiments, from about 70 wt. % to about 90 wt. % of the blend, as well as from about 30 wt. % to about 75 wt. %, in some embodiments from about 35 wt. % to about 70 wt. %, and in some embodiments, from about 40 wt. % to about 65 wt. % of the entire polymer composition. Likewise, impact modifier(s) (e.g., polybutadienes) may constitute from about 5 wt. % to about 60 wt. %, in some embodiments from about 8 wt. % to about 40 wt. %, and in some embodiments, from about 10 wt. % to about 30 wt. % of the blend, as well as from about 1 wt. % to about 25 wt. %, in some embodiments from about 2 wt. % to about 20 wt. %, and in some embodiments, from about 3 wt. % to about 15 wt. % of the entire polymer composition. Suitable polybutadiene polymers are described in U.S. Patent Publication No. 2016/028061 to Brambrink, et al. and may include, for instance, copolymers containing a butadiene monomer in combination with a styrene monomer (e.g., styrene, α-methylstyrene, alkyl-substituted styrene, etc.) and/or nitrile monomer (e.g., acrylonitrile, methacrylonitrile, alkyl-substituted acrylonitrile, etc.). For example, the butadiene copolymer may be a polybutadiene rubber grafted with styrene and/or acrylonitrile, such as acrylonitrile-butadiene-styrene (“ABS”).

### II. Power Electronics Module

As indicated above, the polymer composition is generally employed in a power electronic module that contains a power converter (e.g., inverter, rectifier, voltage converter, etc., as well as combinations thereof) within a housing. More particularly, the housing contains the polymer composition. The housing may, for instance, include a base that contains a sidewall extending therefrom. A cover may also be supported on the sidewall of the base to define an interior within which the electronic component(s) are received and protected from the exterior environment. Regardless of the particular configuration of the module, the polymer composition of the present invention may be used to form all or a portion of the housing and/or cover. In one embodiment, for instance, the polymer composition of the present invention may be used to form the base and sidewall of the housing. In such embodiments, the cover may be formed from the polymer composition of the present invention or from a different material, such as a metal component (e.g., aluminum plate). The polymer composition may generally be employed to form the housing or a portion of the housing using a variety of different shaping techniques. Suitable techniques may include, for instance, injection molding, low-pressure injection molding, extrusion compression molding, gas injection molding, foam injection molding, low-pressure gas injection molding, low-pressure foam injection molding, gas extrusion compression molding, foam extrusion compression molding, extrusion molding, foam extrusion molding, compression molding, foam compression molding, gas compression molding, etc. For example, an injection molding system may be employed that includes a mold within which the composition may be injected. The time inside the injector may be controlled and optimized so that polymer matrix is not pre-solidified. When the cycle time is reached and the barrel is full for discharge, a piston may be used to inject the composition to the mold cavity. Compression molding systems may also be employed. As with injection molding, the shaping of the composition into the desired article also occurs within a mold. The composition may be placed into the compression mold using any known technique, such as by being picked up by an automated robot arm. The temperature of the mold may be maintained at or above the solidification temperature of the polymer matrix for a desired time period to allow for solidification. The molded product may then be solidified by bringing it to a temperature below that of the melting temperature. The resulting product may be de-molded. The cycle time for each molding process may be adjusted to suit the polymer matrix, to achieve sufficient bonding, and to enhance overall process productivity. Due to the unique properties of the composition, relatively thin shaped housing portions (e.g., injection molded parts) can be readily formed therefrom. For example, such housing portions may have a thickness of about 10 millimeters or less, in some embodiments about 8 millimeters or less, in some embodiments about 6 millimeters or less, in some embodiments from about 0.4 to about 5 millimeters, and in some embodiments, from about 0.8 to about 4 millimeters (e.g., 0.8, 1.2. or 3 millimeters).

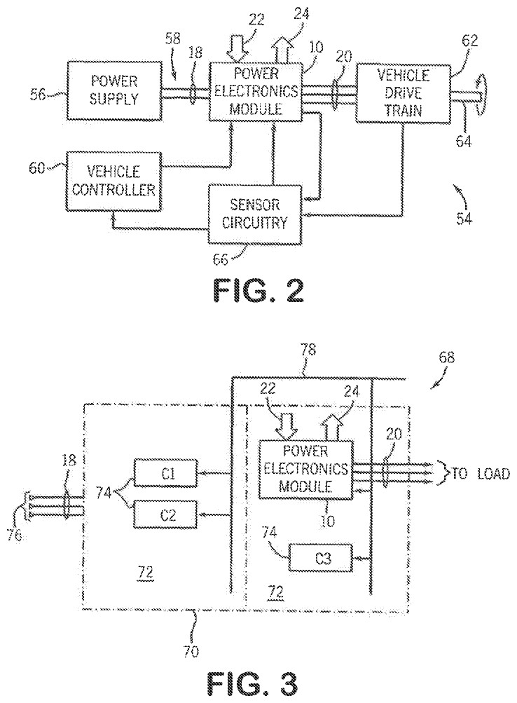

The power electronics module may be used in a wide variety of applications. For example, the electronic module may be employed in an automotive vehicle (e.g., electric vehicle). FIGS. 2-3 illustrate exemplary applications of power electronics modules for use in an automotive vehicle. In the illustration of FIG. 2, for instance, a vehicle drive 54 is provided, such as a drive for an automobile or other mobile application. The vehicle drive 54, which may include the functional circuits of FIG. 2 as well as a wide array of additional support, control, feedback and other interrelated components, will generally include a power supply 56 that provides the power needed for driving the vehicle. In a typical application, the power supply 56 may include one or more batteries, generators or alternators, fuel cells, utility source, alternators, voltage regulators, and so forth. Power supply 56 applies power, typically in the form of direct current via direct current conductors 58 to the power electronics module 10. Control circuitry 60 provides control signals for regulating operation of the power electronics module, such as for speed control, torque control, acceleration, braking, and so forth. Based upon such control signals, power electronics module 10 outputs alternating current waveforms along output conductors, as indicated generally at reference numeral 20 in FIG. 2. The output power is then applied to a vehicle drive train as indicated generally at reference numeral 62. As will appreciated by those skilled in the art, such drive trains will typically include one or more alternating current electric motors which are driven in rotation based upon the frequency and power levels of the signals applied by the power electronics module 10. The vehicle drive train may also include power transmission elements, shafts, gear trains, and the like, ultimately designed to drive one or more output shafts 64 in rotation. Sensor circuitry 66 is provided for sensing operating characteristics of both the vehicle, the drive train, and the power electronics module. The sensor circuitry 66 typically collects such signals and applies them to the control circuitry, such as for regulation of speeds, torques, power levels, temperatures, flow rates of coolants, and the like.

FIG. 3 illustrates a further application of a power electronics module 10. In the system, designated generally by reference numeral 68, an enclosure 70 is provided that may be divided into bays 72. Within each bay various components are mounted and interconnected for regulating operation of processes. The components, designated generally by reference numeral 74, are mounted within the bays and receive power via an alternating current bus 76. A control network 78 applies control signals for regulating operation of the components 74 and of the power electronics module 10. An enclosure, such as enclosure 70 may be included in various settings, such as for driving one or more drive trains of an automobile, utility vehicle, transport or other vehicle.

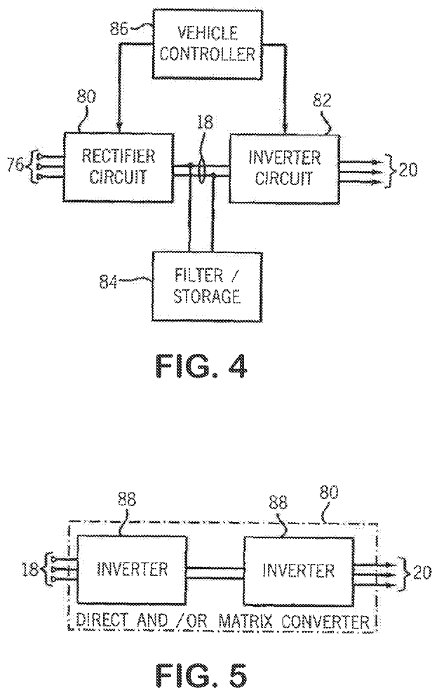

As mentioned above, various circuit configurations may be designed into the power electronics module. The circuit configurations will vary widely depending upon the particular requirements of each individual application. However, certain exemplary circuit configurations are presently envisaged, both of which include power electronic devices which require robust and compact packaging along with thermal management. Two such exemplary circuits are illustrated in FIGS. 4-5. In FIG. 4, the circuitry includes a rectifier circuit 80 that converts alternating current power from a bus 76 to direct current power for output along a DC bus, corresponding to incoming power lines 18. An inverter circuit 82 receives the direct current power and converts the direct current power to alternating current waveforms at desired frequencies and amplitudes. The alternating current power may then be applied to a load via the outgoing conductors 20. Filter and storage circuitry 84 may be coupled across the direct current bus to smooth and condition the power applied to the bus. A control circuit 86 regulates operation of the rectifier and inverter circuits. In the example of FIG. 5, an inverter (not shown) receives incoming alternating current power and supplies an outgoing waveform to power switches 88. The set of AC switches effectively convert fixed frequency incoming power 18 to controlled frequency outgoing power 20 for application to a load. It should be borne in mind, however, that the particular circuitry of FIGS. 4-5 is exemplary only, and any range of power electronic circuits may be adapted for incorporation into a module in accordance with the present techniques.

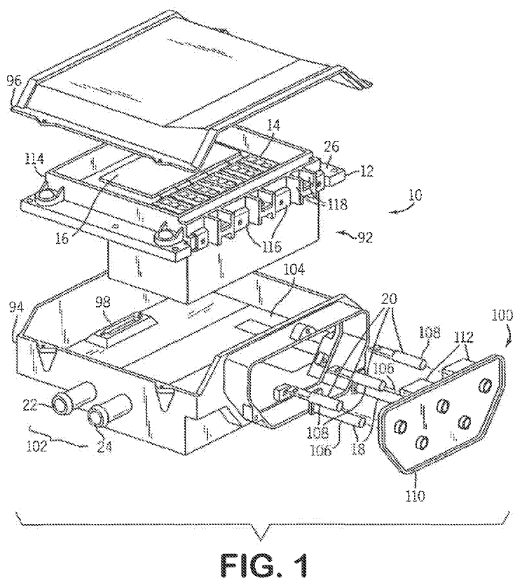

FIG. 1 illustrates an exemplary physical configuration for a power electronics module 10. In the embodiment of FIG. 1, a circuit assembly 92 is positioned within a housing that contains a housing portion 94 enclosed by a cover 96. Control and driver circuitry are also disposed on the thermal support for regulating operation of the power electronic circuit with cooling of such circuitry. In the embodiment of FIG. 1, the module is particularly configured for operating as an inverter drive for a vehicle application. Incoming direct current power is received via conductors 18, and converted to three-phase waveforms output via conductors 20. In the embodiment of FIG. 1, a housing portion 94 presents a control interface 98 that is designed to permit control signals to be received within and transmitted from the housing. The control interface may be provided on a bottom side of the housing as illustrated in FIG. 1, or at other positions on the housing. If desired, all or a portion of the housing portion 94 and/or cover 96 may be formed from the polymer composition of the present invention.

A power interface, designated generally by reference numeral 100 in FIG. 1, is provided for transmitting power to and from the circuit assembly 92. Various configurations can be provided and are presently envisaged for interfacing the module 10 with external circuitry. In the embodiment of FIG. 1, for example, the power interface 100 permits five conductors—i.e., two direct current conductors and three alternating conductors—to be directly interfaced from the circuit assembly, such as in a plug-in arrangement. In addition to the control and power interfaces, a coolant interface 102 may be provided for receiving and circulating coolant. In the illustrated embodiment, housing portion 94 includes a cavity 104 in which circuit assembly 92 is disposed. Conductors 106 transmit DC power to the circuit assembly 92, while conductors 108 transmit the AC waveforms from the circuit assembly 92 for application to a load. An interface plate 110 is provided through which conductors 106 and 108 extend. Where desired, sensors may be incorporated into the assembly, such as current sensors 112 which are aligned about two of the outgoing power conductors 108 to provide feedback regarding currents output by the module. As will be appreciated by those skilled in the art, other types and numbers of sensors may be employed, and may be incorporated both within the housing, within a connector assembly, or within the circuit assembly itself.

Although by no means required, the circuit assembly 92 may include a thermal support 12 on which power electronic circuit 14 is disposed. The thermal support 12 may incorporate a variety of features designed to improve support, both mechanical and electrical, for the various components mounted thereon. Certain of these features may be incorporated directly into the thermal support, or may be added, as is the case of the embodiment of FIG. 1. As shown in FIG. 1, a frame 114, made of a non-metallic material in this embodiment, is fitted to the thermal support 12, and components mounted to the thermal support are at least partially surrounded by the frame. The frame serves both as an interface for conductors 106 and 108, and for surrounding circuitry supported on thermal support 12 to receive an insulating or potting medium. In the embodiment of FIG. 1 terminals 116 are formed on frame 114, and may be embedded within the frame during molding of the frame from an insulative material. A preferred configuration for the terminals is described more fully below. Separators 118 partially surround terminals 116 for isolating the conductors coupled to the terminals from one another.

The present invention may be better understood by reference to the following examples.

### Test Methods

Thermal Conductivity: In-plane and through-plane thermal conductivity values are determined in accordance with ASTM E1461-13.

Electromagnetic Interference (“EMI”) Shielding: EMI shielding effectiveness may be determined in accordance with ASTM D4935-18 at frequency ranges ranging from 30 MHz to 1 GHz (e.g., 30 MHz, 50 MHz, or 100 MHz). The thickness of the parts tested may vary, such as 1 millimeter, 1.5 millimeters, 1.6 millimeters, or 3 millimeters. The test may be performed using an EM-2107A standard test fixture, which is an enlarged section of coaxial transmission line and available from various manufacturers, such as Electro-Metrics. The measured data relates to the shielding effectiveness due to a plane wave (far field EM wave) from which near field values for magnetic and electric fields may be inferred.

Surface/Volume Resistivity: The surface and volume resistivity values are generally determined in accordance with ASTM D257-14. For example, a standard specimen (e.g., 1 meter cube) may be placed between two electrodes. A voltage may be applied for sixty (60) seconds and the resistance may be measured. The surface resistivity is the quotient of the potential gradient (in V/m) and the current per unit of electrode length (in A/m), and generally represents the resistance to leakage current along the surface of an insulating material. Because the four (4) ends of the electrodes define a square, the lengths in the quotient cancel and surface resistivities are reported in ohms, although it is also common to see the more descriptive unit of ohms per square. Volume resistivity may also be determined as the ratio of the potential gradient parallel to the current in a material to the current density. In SI units, volume resistivity is numerically equal to the direct-current resistance between opposite faces of a one-meter cube of the material (ohm-m).

Tensile Modulus, Tensile Stress, and Tensile Elongation at Break: Tensile properties may be tested according to ISO 527-1:2019 (technically equivalent to ASTM D638-14). Modulus and strength measurements may be made on a dogbone-shaped test strip sample having a length of 170/190 mm, thickness of 4 mm, and width of 10 mm. The testing temperature may be −30° C., 23° C., or 80° C. and the testing speeds may be 1 or 5 mm/min.

Flexural Modulus, Flexural Elongation at Break, and Flexural Stress: Flexural properties may be tested according to ISO 178:2019 (technically equivalent to ASTM D790-17). This test may be performed on a 64 mm support span. Tests may be run on the center portions of uncut ISO 3167 multi-purpose bars. The testing temperature may be −30° C., 23° C., or 80° C. and the testing speed may be 2 mm/min.

Charpy Impact Strength: Charpy properties may be tested according to ISO 179-1:2010) (technically equivalent to ASTM D256-10, Method B). This test may be run using a Type 1 specimen size (length of 80 mm, width of 10 mm, and thickness of 4 mm). Specimens may be cut from the center of a multi-purpose bar using a single tooth milling machine. The testing temperature may be −30° C., 23° C., or 80° C.

Deflection Temperature Under Load (“DTUL”): The deflection under load temperature may be determined in accordance with ISO 75-2:2013 (technically equivalent to ASTM D648-07). More particularly, a test strip sample having a length of 80 mm, width of 10 mm, and thickness of 4 mm may be subjected to an edgewise three-point bending test in which the specified load (maximum outer fibers stress) was 1.8 Megapascals. The specimen may be lowered into a silicone oil bath where the temperature is raised at 2° C. per minute until it deflects 0.25 mm (0.32 mm for ISO Test No. 75-2:2013).

### Example 1

Sample 1 is a commercially available polymer composition that contains approximately 85-90 wt. % of nylon 6,6, 10 wt. % of stainless steel long fibers, and 0-5 wt. % of other additives. The composition is formed from a combination of first and second polymer pellets. More particularly, the first pellets are long-fiber pellets containing 50 wt. % of the stainless steel long fibers and 50 wt. % of resin components, and are formed using a pultrusion process as described herein. The second pellets contain no steel fibers and 100 wt. % of the remaining resin components, and are formed by melt-processing the components in an extruder. The first and second pellets are tumbled together to form a dry blend that is then injected molded into a shaped part for use in a power converter.

### Example 2

Sample 2 is a commercially available composition formed in the same manner as described in Example 1, except that polybutylene terephthalate (PBT) is employed as the thermoplastic polymer rather than nylon 6,6.

### Example 3

Sample 3 is a commercially available composition formed in the same manner as described in Example 1, except that an aromatic polycarbonate (PC) is employed as the thermoplastic polymer rather than nylon 6,6.

### Example 4

Sample 4 is a commercially available composition formed in the same manner as described in Example 1, except that a propylene polymer is employed as the thermoplastic polymer rather than nylon 6,6.

### Example 5

Sample 5 is a commercially available composition formed in the same manner as described in Example 1, except that polyphenylene sulfide (PPS) is employed as the thermoplastic polymer rather than nylon 6,6.

### Example 6

Sample 6 is a commercially available composition formed in the same manner as described in Example 5, except that the polyarylene sulfide is present in an amount of 75-80 wt. % and the stainless steel long fibers are present in an amount of 20 wt. % of the composition.

### Example 7

Sample 7 is a commercially available polymer composition that contains approximately 35-50 wt. % of polyphenylene sulfide (PPS), 40-55 wt. % graphite, and 10 wt. % glass fibers. The composition is formed by melt-processing the components in an extruder. The resulting composition is then injected molded into a shaped part for use in a power converter.

### Example 8

Sample 8 is a commercially available polymer composition that contains approximately 75-80 wt. % of a mixture of polyamides (20 wt. % nylon 6 and 80 wt. % nylon 6,6), 20 wt. % carbon fibers, and 0-5 wt. % of other additives. The composition is formed by melt-processing the components in an extruder. The resulting composition is then injection molded into a shaped part for use in a power converter.

### Example 9

Sample 9 is a commercially available polymer composition that contains approximately 80-85 wt. % of polybutylene terephthalate (PBT), 15 wt. % carbon fibers, and 0-5 wt. % of other additives. The composition is formed by melt-processing the components in an extruder. The resulting composition is then injection molded into a shaped part for use in a power converter.

### Example 10

Sample 10 is a commercially available polymer composition that contains approximately 30-40 wt. % of a thermotropic liquid crystalline polymer (LCP) and 60-70 wt. % mesophase pitch-based carbon fibers. The composition is formed by melt-processing the components in an extruder. The resulting composition is then injection molded into a shaped part for use in a power converter.

Samples 1-10 were also tested for mechanical properties, thermal properties, and electrical properties as described herein. The results are set forth below in Tables 1-3.

TABLE 1
Mechanical and Thermal Properties

| | | | | | | | | Thermal |
|---|---|---|---|---|---|---|---|---|
| | | | | | | | DTUL | Conductivity, in- |
| | Tensile | Tensile | Tensile | Flex | Flex | Notched | (° C.) | plane, flow |
| | Strength | Modulus | Elongation | Strength | Modulus | Charpy | @1.8 | direction |
| Sample | (MPa) | (MPa) | (%) | (MPa) | (MPa) | (kJ/m²) | MPa | (W/mK) |
| 1 | 79 | 4,140 | 2.6 | 125 | 3,450 | 4.0 | 80 | — |
| 2 | 60 | 3,410 | 2.8 | 100 | 3,320 | 3.0 | 57 | — |
| 3 | 68 | 2,760 | 4.0 | 97 | 2,740 | 9.0 | 133 | — |
| 4 | 32 | 1,380 | 7.9 | 46 | 2,070 | 2.1 | 54 | — |
| 5 | 49 | 4,720 | 1.1 | 137 | 4,720 | — | — | — |
| 6 | 98 | 10,000 | 1 | 180 | 10,200 | 4.0 | — | — |
| 7 | 44 | 11,600 | 0.4 | 76 | 13,000 | — | 248 | 20 |
| 8 | 205 | 14,900 | 2.7 | — | — | 8 | 240 | — |
| 9 | 135 | 12,500 | 3.4 | — | — | 5 | — | — |
| 10 | 81 | 21,000 | 0.4 | 160 | 41,000 | 8.5 (un- | 268 | 16.5 |
| | | | | | | notched) | | |

TABLE 2
Electrical Properties (Low Frequency)

| | | Average EMI Shielding | Average EMI Shielding | Average EMI Shielding | |
|---|---|---|---|---|---|
| | EMI Shielding | Effectiveness (SE) at | Effectiveness (SE) at | Effectiveness (SE) at | |
| | Effectiveness (SE) | 3 mm thickness for | 1.6 mm thickness for | 3 mm thickness for | Volume |
| | at 30 MHz and | frequency range of | frequency range of | frequency range of | Resistivity |
| Sample | 3 mm thickness | 30 MHz-1.5 GHz | 1.5 GHz-10 GHz | 1 GHz-18 GHz | (Ohm-cm) |
| 1 | 56.4 | 58.8 | 55.9 | 57.3 | <0.5 |
| 2 | 56.4 | 59.0 | 53.8 | 55.5 | <0.5 |
| 3 | 55.2 | 58.9 | 60.1 | 55.2 | <0.5 |
| 4 | 55.2 | 58.7 | 52.6 | 54.1 | <0.5 |
| 5 | 56.4 | 58.5 | 55.5 | 57.8 | <0.5 |
| 6 | 57.9 | 36.9 | 54.6 | 57.0 | <0.5 |
| 7 | 35.7 | 36.9 | 47.0 | 55.9 | 0.2 |
| 8 | 37.4 | 36.9 | 45.5 | 49.6 | 1,000 |
| 9 | 29.6 | 29.9 | 42.9 | 37.2 | 20,000 |

TABLE 3
Electrical Properties (2-16 GHz)

| | EMI Shielding Effectiveness (SE) at 3 mm thickness | | | | | | | |
|---|---|---|---|---|---|---|---|---|
| Sample | 2 GHz | 4 GHz | 6 GHz | 8 GHz | 10 GHz | 12 GHz | 14 GHz | 16 GHz |
| 1 | 56.69 | 60.77 | 54.68 | 58.93 | 52.91 | 50.52 | 54.24 | 56.60 |
| 2 | 55.44 | 63.16 | 55.96 | 56.19 | 51.70 | 54.73 | 57.79 | 54.12 |
| 3 | 37.70 | 53.37 | 46.57 | 47.61 | 53.28 | 53.48 | 53.14 | 56.18 |
| 4 | 52.15 | 59.51 | 52.44 | 51.71 | 53.76 | 50.22 | 53.86 | 59.71 |
| 5 | 47.57 | 47.91 | 41.75 | 43.09 | 47.78 | 49.29 | 52.64 | 49.49 |
| 6 | 53.75 | 59.47 | 56.24 | 61.39 | 54.91 | 52.06 | 57.78 | 54.67 |
| 7 | 40.53 | 39.88 | 48.97 | 44.03 | 49.64 | 51.76 | 56.14 | 56.00 |
| 8 | 33.79 | 32.93 | 29.88 | 34.96 | 39.22 | 41.88 | 49.56 | 50.38 |
| 9 | 24.31 | 20.84 | 19.71 | 17.07 | 20.71 | 24.66 | 26.80 | 27.43 |

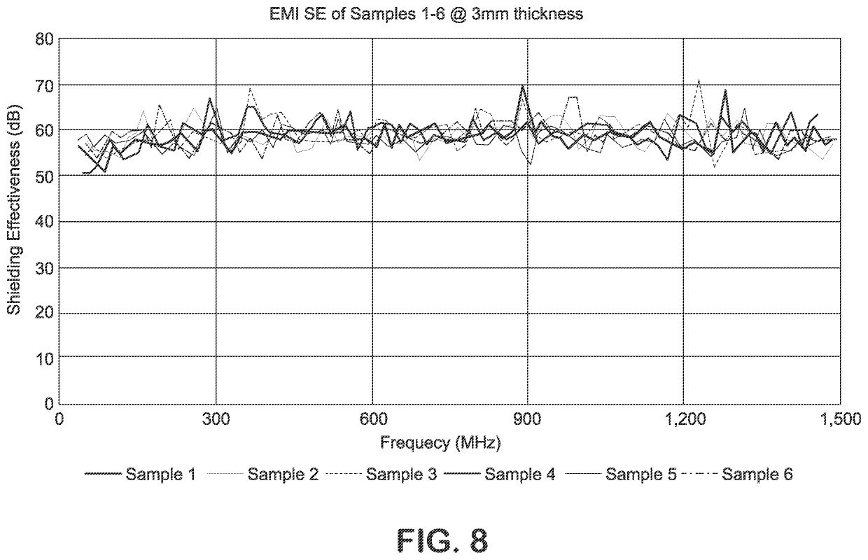

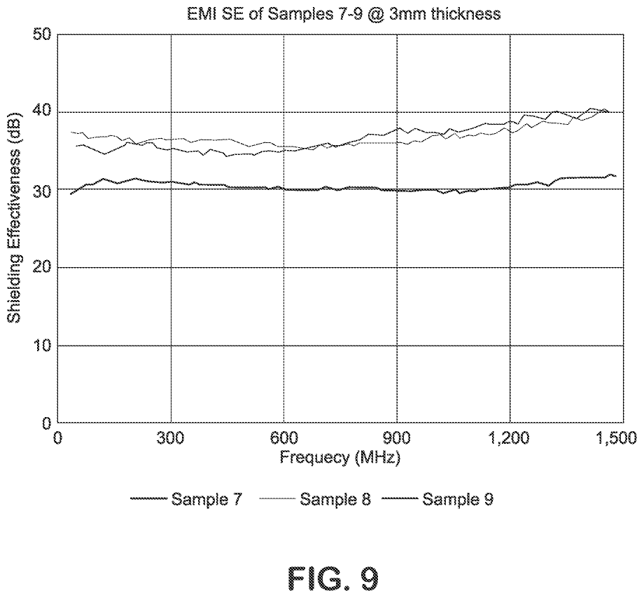

FIGS. 8-9 also show the shielding effectiveness (“SE”) for Samples 1-4 (thickness of 3 mm) over a frequency range from 30 MHz to 1.5 GHz.

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A power electronic module comprising a housing that receives at least one power converter, wherein the housing contains a polymer composition that includes an electromagnetic interference filler distributed within a polymer matrix, wherein the polymer matrix contains a thermoplastic polymer having a deflection temperature under load of about 40° C. or more as determined in accordance with ISO 75-2:2013 at a load of 1.8 MPa, further wherein the composition exhibits an electromagnetic interference shielding effectiveness of about 25 decibels or more as determined in accordance with ASTM D4935-18 at a frequency of 30 MHz and thickness of 3 millimeters.

2. The power electronics module of claim 1, wherein the polymer composition exhibits an average electromagnetic interference shielding effectiveness of about 25 decibels or more over a frequency range of from about 100 kHz to about 1.5 GHz and at a thickness of 3 millimeters.

3. The power electronics module of claim 1, wherein the polymer composition exhibits an average electromagnetic interference shielding effectiveness of about 25 decibels or more over a frequency range of from about 30 MHz to about 100 MHz and at a thickness of 3 millimeters.

4. The power electronics module of claim 1, wherein the polymer composition exhibits an average electromagnetic interference shielding effectiveness of about 25 decibels or more over a frequency range of from about 150 kHz to about 30 MHz and at a thickness of 3 millimeters.

5. The power electronics module of claim 1, wherein the polymer composition exhibits an average electromagnetic interference shielding effectiveness of about 25 decibels or more over a frequency range of from about 1.5 GHz to about 10 GHz and at a thickness of 1.6 millimeters.

6. The power electronics module of claim 1, wherein the polymer composition exhibits a volume resistivity of about 25,000 oh-cm or less as determined in accordance with ASTM D257-14.

7. The power electronics module of claim 1, wherein the polymer composition exhibits a volume resistivity of about 1,000 oh-cm or less as determined in accordance with ASTM D257-14.

8. The power electronics module of claim 1, wherein the polymer composition exhibits an in-plane thermal conductivity of about 1 W/m-K or more as determined in accordance with ASTM E 1461-13.

9. The power electronics module of claim 1, wherein the polymer matrix constitutes from about 30 wt. % to about 99 wt. % of the composition.

10. The power electronics module of claim 1, wherein the thermoplastic polymer has a glass transition temperature of about 10° C. or more.

11. The power electronics module of claim 1, wherein the thermoplastic polymer has a melting temperature of about 140° C. or more.

12. The power electronics module of claim 1, wherein the thermoplastic polymer includes an aromatic polymer.

13. The power electronics module of claim 12, wherein the aromatic polymer is an aromatic polyester.

14. The power electronics module of claim 13, wherein the aromatic polyester is poly(ethylene terephthalate), poly(1,4-butylene terephthalate), poly(1,3-propylene terephthalate), poly(1,4-butylene 2,6-naphthalate), poly(ethylene 2,6-naphthalate), poly(1,4-cyclohexylene dimethylene terephthalate), or a combination thereof.

15. The power electronics module of claim 12, wherein the aromatic polymer is a polyarylene sulfide.

16. The power electronics module of claim 12, wherein the aromatic polymer is an aromatic polycarbonate.

17. The power electronics module of claim 12, wherein the aromatic polymer is a thermotropic liquid crystalline polymer.

18. The power electronics module of claim 12, wherein the aromatic polymer is an aromatic polyamide.

19. The power electronics module of claim 1, wherein the thermoplastic polymer includes an aliphatic polymer.

20. The power electronics module of claim 19, wherein the aliphatic polymer includes an aliphatic polyamide.

21. The power electronics module of claim 19, wherein the aliphatic polymer includes a propylene polymer.

22. The power electronics module of claim 1, wherein the electromagnetic interference filler constitutes from about 1 wt. % to about 70 wt. % of the composition.

23. The power electronics module of claim 1, wherein the electromagnetic interference filler includes a metal.

24. The power electronics module of claim 23, wherein the metal includes stainless steel.

25. The power electronics module of claim 23, wherein the electromagnetic interference filler constitutes from about 4 wt. % to about 20 wt. % of the composition.

26. The power electronics module of claim 1, wherein the electromagnetic interference filler includes a carbon material.

27. The power electronics module of claim 26, wherein the carbon material includes carbon fibers, carbon particles, or a combination thereof.

28. The power electronics module of claim 26, wherein the electromagnetic interference filler constitutes from about 30 wt. % to about 60 wt. % of the composition.

29. The power electronics module of claim 1, wherein the electromagnetic interference filler includes particles, flakes, fibers, or a combination thereof.

30. The power electronics module of claim 1, wherein the electromagnetic interference filler contains a plurality of long fibers.

31. The power electronics module of claim 30, wherein the long fibers are spaced apart and aligned in a substantially similar direction.

32. The power electronics module of claim 1, wherein the polymer composition further comprises a thermally conductive filler.

33. The power electronics module of claim 1, wherein the polymer further comprises reinforcing fibers.

34. The power electronics module of claim 33, wherein the reinforcing fibers include glass fibers.

35. The power electronics module of claim 1, wherein the housing includes a base that contains a sidewall extending therefrom and an optional cover supported by the sidewall.

36. The power electronics module of claim 35, wherein the base, sidewall, cover, or a combination thereof contain the polymer composition.

37. The power electronics module of claim 1, wherein the power converter includes an inverter, rectifier, voltage converter, or a combination thereof.

38. An electric vehicle comprising the power electronic module of claim 1.
